(19) United States
(12) Patent Application Publication
(10) Pub. No.: US 2012/0229995 A1
(43) Pub. Date: Sep. 13, 2012

(54) SOLENOID

(76) Inventor: Alan Chapman, Queensland (AU)

(21) Appl. No.: 13/389,471

(22) PCT Filed: Aug. 10, 2010
(86) PCT No.: PCT/AU2010/001010

§ 371 Date: May 21, 2012

(30) Foreign Application Priority Data
Aug. 11, 2009 (AU) 2009903740

(51) Int. Cl. H05K 7/00; H01F 3/00; H05K 1/18; H01F 7/06

(52) U.S. Cl. 361/752; 29/606; 335/209; 174/260; 361/748

(57) ABSTRACT

A solenoid for use with a fuel injector, the solenoid comprising a housing able to be attached to an injector; a core able to be located within the housing; a coil able to be located within the core; and an electrical cable electrically connected to the coil wherein at least the coil and the electrical cable connection to the coil is encapsulated by encapsulant.

### FIELD OF THE INVENTION

This invention relates to a solenoid. In particular, the invention resides in a solenoid for use with a diesel injector for an engine used in underground coal mining machinery and therefore will be described in this context. However, it should be appreciated that the solenoid may be used for other purposes.

### BACKGROUND OF THE INVENTION

Methane is stored under pressure within coal until. mining activities release the methane into the atmosphere. This is a well known phenomenon which all coal mining operations cater for in order to provide safe working conditions for miners. If methane concentrations in an underground mine's atmosphere exceeds 2%, operations are suspended because of the dangerous conditions. This danger is mitigated by strictly enforced mine ventilation safety regulations. Still, methane accumulation in underground mines is responsible for thousands of deaths worldwide every year related to underground mine explosions.

For an underground coal mining explosion to occur, there must be an ignition source. If there is no ignition source, then an explosion cannot occur. However, only a small spark is required to create a methane explosion in an underground coal mine. Accordingly, all machines that operate in an underground coal mine must be designed to prevent the creation of an ignition source of methane.

The majority of machines that are designed to work in an underground coal mine are primarily operated mechanically. That is, the type of electrical components that are used in underground coal mine machinery is regulated to minimise the risk that failure or mal-operation could supply the ignition energy to potentially ignite combustible gases and dusts. The problem is that many engines today are electrically controlled for increased performance and lower emissions. Lower emissions and increased performance are good for underground coal mining machines. However, electrical control increases the risk of an unwanted ignition source often to unacceptable levels.

### OBJECT OF THE INVENTION

It is an object of the invention to overcome and/or alleviate one or more of the above disadvantages and/or provide the consumer with a useful and/or commercial choice.

### SUMMARY OF THE INVENTION

In one form, the invention relates to a solenoid which has a reduced risk of an unwanted ignition source.

In another form, the invention resides in a solenoid for use with a fuel injector, the solenoid comprising:

a housing able to be attached to an injector;
a core able to be located within the housing;
a coil able to be located within the core; and
an electrical cable electrically connected to the coil.

Preferably, the housing is made from a non-magnetic material. For example, the housing may be made of brass or non-magnetic stainless steel or high performance non-metallic compounds or the like materials.

Preferably, the housing, coil and core are all flush with each other at one end of the solenoid. Normally, housing, core and coil are machined to so that the housing, coil and core are all flush with each other.

Normally, at least the coil is encapsulated with encapsulant. The core may have a least one slot for the purpose of encapsulation. Preferably, the core has two slots to assist with encapsulation via encapsulant. The core is typically made from a magnetic material.

A printed circuit board may be used to electrically connect the electrical cable to the coil. The printed circuit board may be formed with at least one track that may substantially mirror the temperature of the coil. A thermal fuse may be mounted to the printed circuit board and connected to tracks of the printed circuit board. Normally, the thermal fuse is located adjacent to the at least one track of the printed circuit board that substantially mirrors the temperature of the coil.

Encapsulant may also be used to encapsulate the printed circuit board, thermal fuse and electrical cable terminations.

A strain relief may be attached to the housing with the electrical cable passing through the housing.

In another form, the invention resides in a method of producing a solenoid including the steps of:

locating a coil within a core;
locating a core within a housing; and
connecting the coil to an electrical cable.

The method may further include one or more of the steps of:

encapsulating the coil with encapsulant;
connecting the coil to an electrical cable via a printed circuit board;
attaching a thermal fuse to the printed circuit board;
locating the thermal fuse adjacent the printed circuit board;
locating the electrical cable through a strain relief and/or
encapsulating the printed circuit board, thermal fuse and electrical cable with encapsulant.

### BRIEF DESCRIPTION OF THE DRAWINGS

An embodiment, by way of example only, will be described with reference to the accompanying drawings in which:

FIG. 1 is an exploded perspective view of a solenoid according to an embodiment of the invention;

FIG. 2 is a further exploded perspective view of a solenoid according to FIG. 1;

FIG. 3 is a front view of a solenoid according to FIG. 1;

FIG. 4 is a sectional view of a solenoid according to FIG. 1;

FIG. 5 is a sectional view of a coil;

FIG. 6 is a front view of a bobbin;

FIG. 7 is a sectional view of a bobbin;

FIG. 8 is a schematic view of a printed circuit board;

FIG. 9 is a schematic view of a printed circuit board attached to a thermal fuse, electrical cable and winding ends;

FIG. 10 is a perspective view of a core;

FIG. 11 is a further perspective view of a core;

FIG. 12 is an exploded perspective view of a solenoid attached to a diesel injector; and

FIG. 13 is a perspective view of a solenoid attached to a diesel injector.

### DETAILED DESCRIPTION OF THE PREFERRED EMBODIMENT

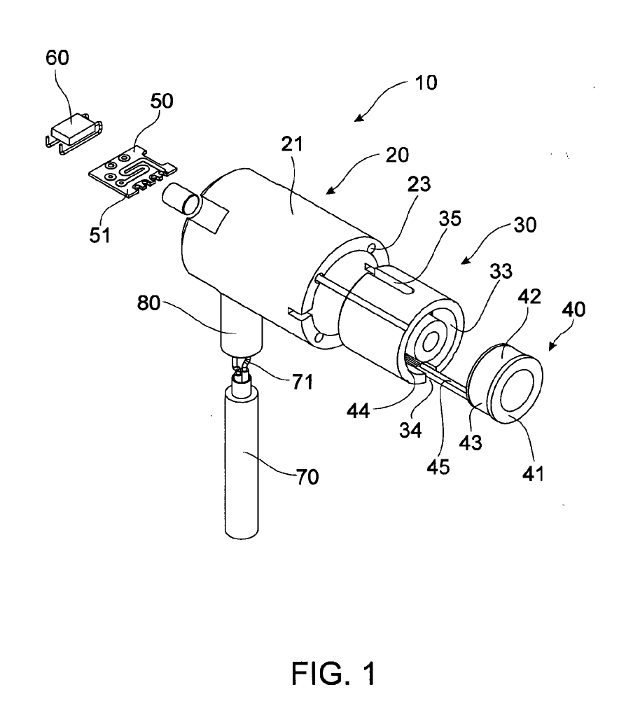

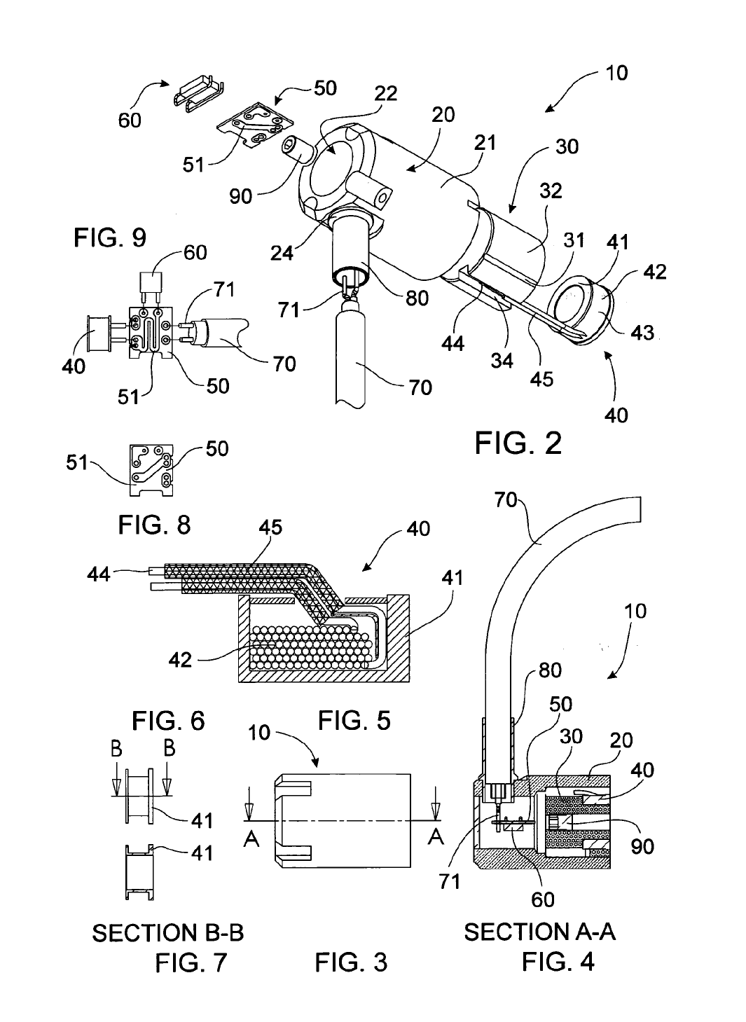

FIGS. 1 to 4 show a solenoid 10 for use with a diesel injector. The solenoid 10 includes a housing 20, a core 30 and a coil 40.

The housing 20 is used to house the core 30 and the coil 40. The housing 20 is hollow, substantially cylindrical in shape, and made of brass. As the housing 20 is hollow, the housing 20 has a housing outer wall 21 and a housing inner wall 22. Four bolt holes 23 extend through the housing 20 and are used to attach the housing 20 to a diesel injector. The four bolt holes 23 penetrate the housing inner wall 22. A strain relief hole 24 is located adjacent the top of the housing 20 extending from the housing outer wall 21 to the housing inner wall 22.

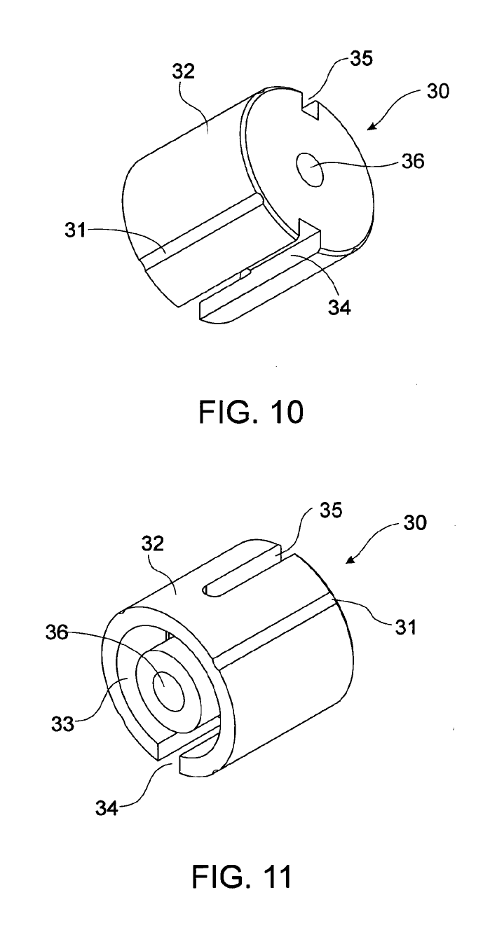

The core 30, shown in more detail in FIGS. 10 and 11, is made from magnetic material, such as magnetic steel. The core 30 is cylindrical in shape with four bolt grooves 31 that extend down a core outer wall 32. A coil recess 33 is located at one end of the core 30. A wire slot 34 extends the length of the core 30 and is in communication with the coil recess 33. Similarly, an encapsulation slot 35, which is diametrically opposed to the wire slot 34, extends partially down the core outer wall 32 of the core 30. An encapsulation hole (not shown) extends between the encapsulation slot 35 and the coil recess 33. A pin aperture 36 extends through the core 30.

The coil 40, as shown in more detail in FIGS. 5 to 7, is used to create a magnetic field. The coil 40 includes a hollow plastic bobbin 41 with a copper winding 42 extending around the bobbin 41. An insulating tape 43 is wrapped around the copper winding 42. The insulating tape 43 is typically made from fibreglass but may be made from other materials common in the art. The winding ends 44 extend upwardly into the housing 20. The winding ends 44 are fitted with additional insulating sleeves 45.

A printed circuit board 50, shown in more detail in FIG. 8, having a series of electrical tracks 51 is electrically connected to the winding ends 44 as shown in FIG. 9. A thermal fuse 60 is also electrically connected to the tracks 51 of printed circuit board 50 and located adjacent the printed circuit board 50. Electrical cable wires 71 of an electrical cable are also connected to the tracks 51 of printed circuit board 50 as well as a controller (not shown).

The printed circuit board 50 guarantees the physical clearance between the connections of the thermal fuse 60, cable wires 71 and winding ends 44 and the housing 20. Further, the cross-section of a track 51 on the printed circuit board 50 mirrors the cross section of the winding 42 of the coil 40. Hence, the track 51 of the printed circuit board 50 reflects the physical properties of the winding 42 of the coil 40. According, if the temperature of the winding 42 of the coil 40 becomes too high, the temperature of the track 51 on the printed circuit board 50 will mirror the high temperature. This causes the thermal fuse 60 to break preventing operation of the solenoid 10 by disconnection of the supply current provided by the electrical cable 70.

A strain relief 80 is located through the strain relief hole 24 in the housing 20 and extends outwardly from the housing 20. The strain relief 80 is typically made from non-metallic stainless steel.

A thrust plug 90 is located in the pin aperture 36 which extends through the core 30. The thrust plug 90 is threaded to fit in a top threaded portion of the pin aperture 36. The thrust plug 90 is made from non-metallic stainless steel.

In order to produce the solenoid 10, the first step is to fit the core 30 to the housing 20. Loctite™ 620 is applied to the outer wall of the core 30 and the inner wall 22 of the housing 20. The core 30 is then located within the housing 20 using a device such as a bench press. The Loctite ™ is again allowed to cure.

The next step is to fix the coil 40 to the core 30. The coil 40 is located within the coil recess 33 of the core 30 ensuring that the winding ends 44 extend through the wire slot 34 in the core 30. Interference between the bobbin 41 and the core recess 33 ensures that the bobbin 41 (with the associated winding 42) are fixed for the purposes of encapsulation. Again, a bench press may be used for this process.

After the coil 40 has been located within the core 30, the core 30 must be encapsulated by encapsulant (not shown). The encapsulant is Arathane™ although it should be appreciated that other suitable encapsulants may be used. The assembled housing 20, core 30 and coil 40 are all heated in another oven between 60 and 70 degrees Celsius for one hour. The Arathane™ is mixed and then applied to an inside of the housing 20 whilst the core 30 and coil 40 are hot. The viscosity of the applied Arathane™ is reduced by the heated assembly which facilitates the flow of encapsulant through the wire slot 34, the encapsulant slot 35 and the coil recess 33. The housing 20, core 30 and coil 40 and encapsulant are then placed into a vacuum chamber. This ensures that the coil 40 is impregnated with encapsulant. Once encapsulation has been achieved, the housing 20, core 30 and coil 40 are removed from the vacuum chamber and the encapsulant is allowed to cure.

The next step is to ensure the end of the housing 20, core 30 and coil 40 are flush with one another. This is due to the low tolerances that are often associated with the movement that the solenoid 10 is required to initiate. Accordingly, the end of the solenoid 10 is faced ensuring that the bobbin 41 thickness is not less than one millimetre. A lathe is typically used for this process.

The next step is to fit the thrust rod into the coil aperture. Loctite™ is applied to the thrust rod and screwed in to the coil aperture using a set position using a distance setting tool as is known in the art.

The next step is to fit the strain relief 80 to the housing 20. The strain relief 80 is pressed into the strain relief hole 24 of the housing 20. The strain relief 80 is deformed where it protrudes into the housing 20. The method typically uses a punch. The combination of a close fit and the deformed end ensures that the stain relief 80 is securely fixed to the housing 20.

The next step is to connect the thermal fuse 60 of the printed circuit board 50. Insulation (not shown) is provided over leads of the thermal fuse 60 which are then fitted to the tracks 51 of the printed circuit board 50 and soldered into place. The thermal fuse 60 is temporarily immersed in a bath of water to limit the heating of the thermal fuse 60 under the soldering process.

The winding ends 44 are then soldered to the tracks 51 of the printed circuit board 50. The electrical cable 70 is then threaded through the strain relief 80. The cable wires 71 of the electrical cable 70 are then connected to the tracks 51 of the printed circuit board 50. The cable wires 71 are bent over where they penetrate the printed circuit board 50 to increase the strain tolerance.

The next step is to encapsulate a top of the housing 20 covering the thermal fuse 60, winding ends 44, printed circuit board 50 and electrical cable 70. The encapsulant is again Arathane™ which is mixed. Before being applied, the Arathane™ may be degassed using a vacuum and/or heated to about 50 deg C to improve its flow and penetration properties. The top of the housing is then filled with the prepared encapsulant and topped up as required. The stain relief 80 is filled with encapsulant to bind the cable to the stain relief 80 and housing 20. The encapsulant is then allowed to cure.

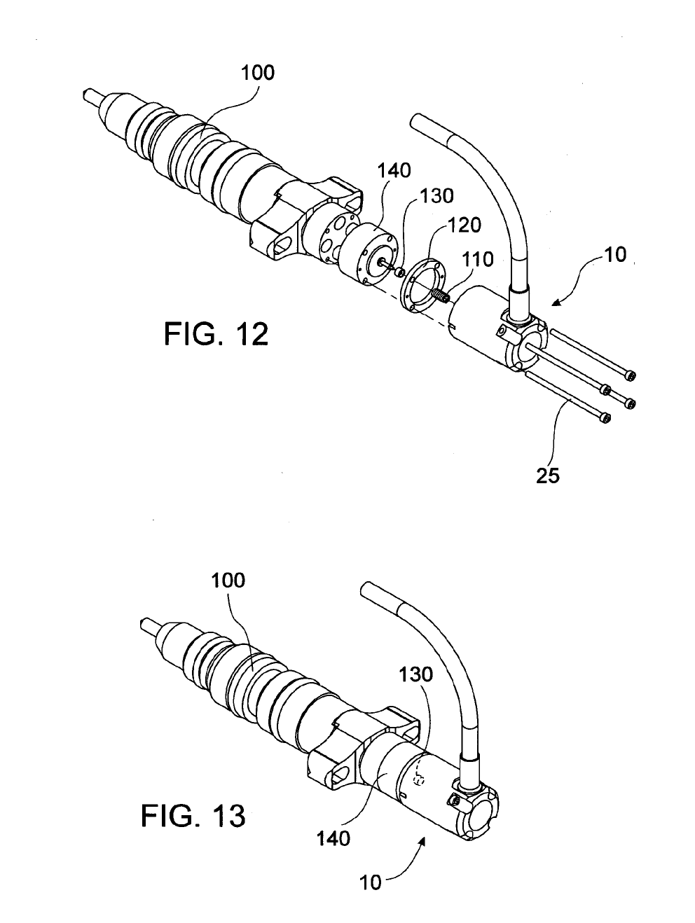

The solenoid 10 can now be used with a diesel injector as shown in FIG. 12 and FIG. 13. In this embodiment, the diesel injector is a Caterpillar™ diesel injector for a caterpillar engine. A spring 110, alloy spacer 120, spring spacer 130 and valve 140 are all located between the solenoid 10 and the diesel injector 100. Four screws 25 are used to hold the solenoid 10 and the diesel injector 100 together and the spring 110, the alloy spacer 120, the spring spacer 130 and the valve 140 in their desired locations. The solenoid 10 operates the diesel injector 100 as is known in the art.

It should be appreciated that various other changes and/or modifications may be made to the embodiment described without departing from the spirit or scope of the invention.

1. A solenoid for use with a fuel injector, the solenoid comprising:
a housing able to be attached to the fuel injector;
a core able to be located within the housing;
a coil able to be located within the core; and
an electrical cable electrically connected to the coil wherein at least the coil and the electrical cable connection to the coil are encapsulated by encapsulant within the housing.

2. The solenoid of claim 1 wherein the housing is made from a non-magnetic material.

3. The solenoid of claim 1 wherein the housing, coil and core are all flush with each other at one end of the solenoid.

4. The solenoid of claim 1 wherein the housing, core and coil are machined to so that the housing, coil and core are all flush with each other.

5. The solenoid of claim 1 wherein the core has at least one slot for encapsulation.

6. The solenoid of claim 5 wherein the core has two slots to assist with encapsulation with encapsulant.

7. The solenoid of claim 1 wherein the core is made from a magnetic material.

8. The solenoid of claim 1 wherein a printed circuit board is used to electrically connect the electrical cable to the coil.

9. The solenoid of claim 8 wherein the printed circuit board is formed with at least one track that substantially mirrors the temperature of the coil.

10. The solenoid of claim 8 wherein a thermal fuse is mounted to the printed circuit board and connected to tracks of the printed circuit board.

11. The solenoid of claim 10 wherein the thermal fuse is located adjacent to the at least one track of the printed circuit board that substantially mirrors the temperature of the coil.

12. The solenoid of claim 10 wherein encapsulant is used to encapsulate the printed circuit board, thermal fuse and electrical cable terminations within the housing.

13. The solenoid of claim 1 wherein a strain relief is attached to the housing with the electrical cable passing through the housing.

14. A method of producing a solenoid including the steps of:
locating a coil within a core;
locating the core within a housing;
connecting the coil to an electrical cable; and encapsulating at least the coil and the electrical cable connection to the coil with encapsulant by applying the encapsulant to the inside of the housing.

15. The method of claim 14 further including the step of connecting the coil to the electrical cable via a printed circuit board.

16. The method of claim 14 further including the step of attaching a thermal fuse to the printed circuit board.

17. The solenoid of claim 1, wherein the housing is metallic.

18. The solenoid of claim 17, wherein the housing is made of brass.
